(19) United States
(12) Patent Application Publication
(10) Pub. No.: US 2025/0285994 A1
(43) Pub. Date: Sep. 11, 2025

(54) SEMICONDUCTOR STRUCTURE AND MANUFACTURING METHOD THEREOF

(71) Applicant: MACRONIX International Co., Ltd., Hsinchu (TW)

(72) Inventor: Yu-Tang Lin, Taipei City (TW)

(73) Assignee: MACRONIX International Co., Ltd., Hsinchu (TW)

(21) Appl. No.: 18/596,630

(22) Filed: Mar. 6, 2024

(51) Int. Cl. H01L 23/58; H01L 21/768; H01L 23/48; H10B 43/27

(52) U.S. Cl. CPC H01L 23/585; H01L 21/76802; H01L 21/76877; H01L 23/481; H10B 43/27

(57) ABSTRACT

A semiconductor structure, applicable to a three-dimensional AND flash memory device, is provided. The semiconductor structure includes a substrate, a dielectric structure, a first seal ring structure, and a first seal via is provided. The substrate includes a device region. The dielectric structure is located on the substrate. The first seal ring structure is located in the dielectric structure. The first seal ring structure surrounds the device region. The first seal via is located in the dielectric structure. The first seal via surrounds the device region. The first seal via is located on the first seal ring structure. The first seal via is in direct contact with the first seal ring structure.

### BACKGROUND

### Technical Field

The invention relates to a semiconductor structure and a manufacturing method thereof, and particularly relates to a semiconductor structure including a seal ring structure and a seal via and a manufacturing method thereof.

### Description of Related Art

In the semiconductor structure, the moisture and the stress are isolated by the seal ring structure and the slit structure. The slit structure is located above the seal ring structure. However, in the etching process for forming the slit structure, the crack is often generated in the dielectric structure. When the crack extends to the underlying conductive layer (e.g., metal layer), the semiconductor structure will be damaged (e.g., peeling) due to expansion of the conductive layer during the subsequent thermal process.

### SUMMARY

The invention provides a semiconductor structure and a manufacturing method thereof, which can prevent the damage to the semiconductor structure.

The invention provides a semiconductor structure, which includes a substrate, a dielectric structure, a first seal ring structure, and a first seal via is provided. The substrate includes a device region. The dielectric structure is located on the substrate. The first seal ring structure is located in the dielectric structure. The first seal ring structure surrounds the device region. The first seal via is located in the dielectric structure. The first seal via surrounds the device region. The first seal via is located on the first seal ring structure. The first seal via is in direct contact with the first seal ring structure.

According to an embodiment of the invention, in the semiconductor structure, the device region may be an active device region or a passive device region.

According to an embodiment of the invention, in the semiconductor structure, the device region may be a memory region.

According to an embodiment of the invention, in the semiconductor structure, the memory region may be a three-dimensional (3D) AND flash memory region.

According to an embodiment of the invention, in the semiconductor structure, the substrate may further include a scribe line region. The scribe line region may surround the device region. The seal ring structure may be located between the device region and the scribe line region.

According to an embodiment of the invention, in the semiconductor structure, the first seal via may be located directly above the first seal ring structure.

According to an embodiment of the invention, in the semiconductor structure, the maximum width of the first seal via may be smaller than the maximum width of the first seal ring structure.

According to an embodiment of the invention, in the semiconductor structure, the material of the first seal ring structure may include metal. The material of the first seal via may include metal.

According to an embodiment of the invention, in the semiconductor structure, the top-view pattern of the first seal via may be a solid ring shape.

According to an embodiment of the invention, the semiconductor structure may further include a second seal ring structure and a second seal via. The second seal ring structure is located in the dielectric structure. The second seal ring structure may surround the first seal ring structure. The second seal via is located in the dielectric structure. The second seal via may surround the first seal via. The second seal via is located on the second seal ring structure. The second seal via may be in direct contact with the second seal ring structure.

According to an embodiment of the invention, in the semiconductor structure, the top-view pattern of the first seal via may be a solid ring shape, and the top-view pattern of the second seal via may be a solid ring shape.

According to an embodiment of the invention, in the semiconductor structure, the top-view pattern of the first seal via may be a solid ring shape, and the top-view pattern of the second seal via may be a dashed ring shape.

According to an embodiment of the invention, in the semiconductor structure, the top-view pattern of the first seal via may be a dashed ring shape, and the top-view pattern of the second seal via may be a solid ring shape.

According to an embodiment of the invention, in the semiconductor structure, the top-view pattern of the first seal via may be a dashed ring shape, and the top-view pattern of the second seal via may be a dashed ring shape.

According to an embodiment of the invention, in the semiconductor structure, the top-view pattern of the first seal via may include first line portions and first openings arranged alternately. The top-view pattern of the second seal via may include second line portions and second openings arranged alternately. The first line portions may be aligned with the second openings. The length of each of the first line portions may be greater than or equal to the length of each of the second openings. The second line portions may be aligned with the first openings. The length of each of the second line portions may be greater than or equal to the length of each of the first openings.

The invention provides a manufacturing method of a semiconductor structure, which includes the following steps. A substrate is provided. The substrate includes a device region. A dielectric structure is formed on the substrate. A first seal ring structure is formed in the dielectric structure. The first seal ring structure surrounds the device region. A first seal via is formed in the dielectric structure. The first seal via surrounds the device region. The first seal via is located on the first seal ring structure. The first seal via is in direct contact with the first seal ring structure.

According to an embodiment of the invention, the manufacturing method of the semiconductor structure may further include the following steps. A stack structure is formed in the dielectric structure in the device region. The stack structure may include dielectric layers and conductive layers arranged alternately. The stack structure may have a staircase portion. Contacts are formed in the dielectric structure. The contacts may be electrically connected to the conductive layers in the staircase portion.

According to an embodiment of the invention, in the manufacturing method of the semiconductor structure, the contacts and the first seal via may be simultaneously formed by the same process.

According to an embodiment of the invention, in the manufacturing method of the semiconductor structure, the substrate may further include a seal ring region. The first seal ring structure and the first seal via are located in the seal ring region. The method of forming the contacts and the first seal via may include the following steps. First openings are formed in the dielectric structure. The first openings are located in the device region and expose the conductive layers. A second opening is formed in the dielectric structure. The second opening is located in the seal ring region and exposes the first seal ring structure. A conductive material layer is formed in the first openings and the second opening and on the dielectric structure. The conductive material layer located outside the first openings and outside the second opening is removed to form the contacts and the first seal via.

According to an embodiment of the invention, the manufacturing method of the semiconductor structure may further include the following steps. A second seal ring structure is formed in the dielectric structure. The second seal ring structure may surround the first seal ring structure. A second seal via is formed in the dielectric structure. The second seal via may surround the first seal via. The second seal via is located on the second seal ring structure. The second seal via may be in direct contact with the second seal ring structure.

Based on the above description, in the semiconductor structure and the manufacturing method thereof according to the invention, the first seal via is located on the first seal ring structure, and the first seal via is in direct contact with the first seal ring structure. In this way, during the process of forming the first seal via, the etching process can be performed on the dielectric structure by using the first seal ring structure as an etch stop layer to form the opening for accommodating the first seal via. Therefore, the dielectric structure can be prevented from cracking during the above etching process, thereby preventing the semiconductor structure from being damaged.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are cross-sectional views of a manufacturing process of a semiconductor structure according to some embodiments of the invention.

FIG. 2A is a top view of a semiconductor structure according to some embodiments of the invention.

FIG. 2B is a top view of a semiconductor structure according to other embodiments of the invention.

FIG. 2C is a top view of a semiconductor structure according to other embodiments of the invention.

FIG. 2D is a top view of a semiconductor structure according to other embodiments of the invention.

FIG. 3A is a circuit diagram of a 3D AND flash memory array according to some embodiments of the invention.

FIG. 3B is a partial perspective view of a part of the memory array in FIG. 3A.

FIG. 3C and FIG. 3D are cross-sectional views taken along section line II-II′ in FIG. 3B.

FIG. 3E is a top view of section line III-III′ in FIG. 3B, FIG. 3C, and FIG. 3D.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

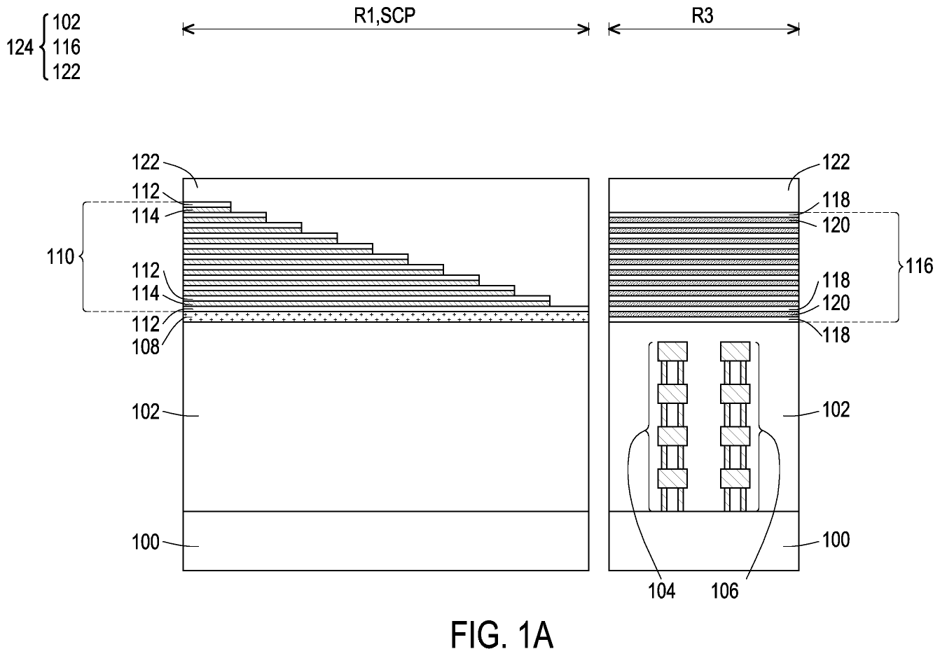

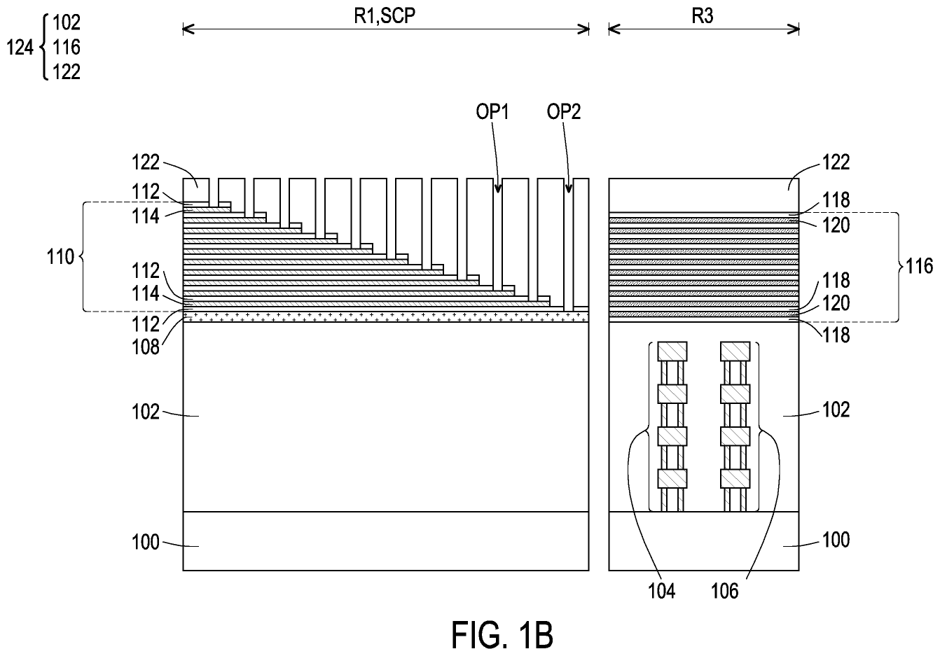

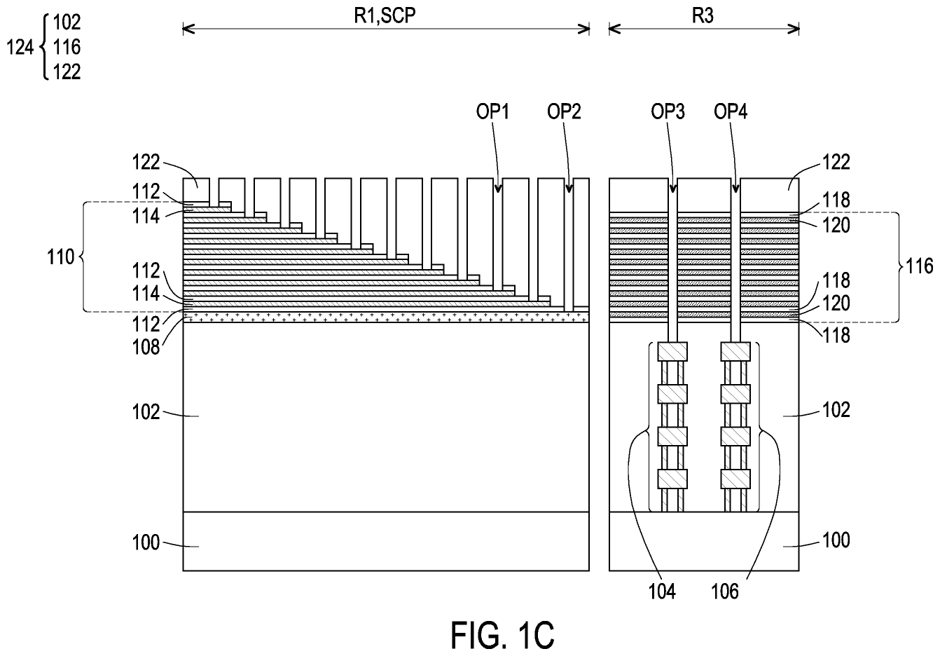

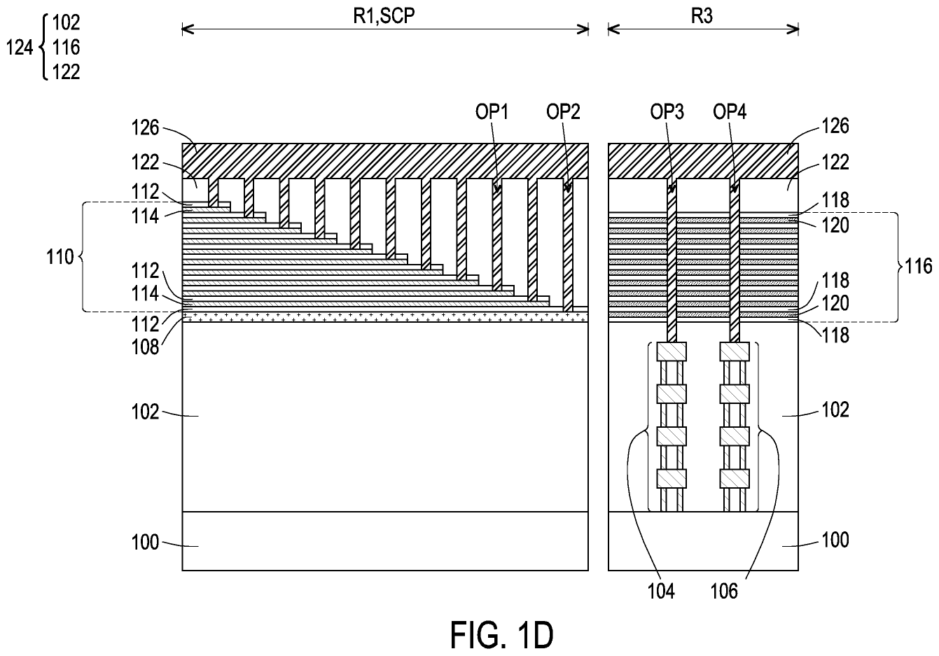

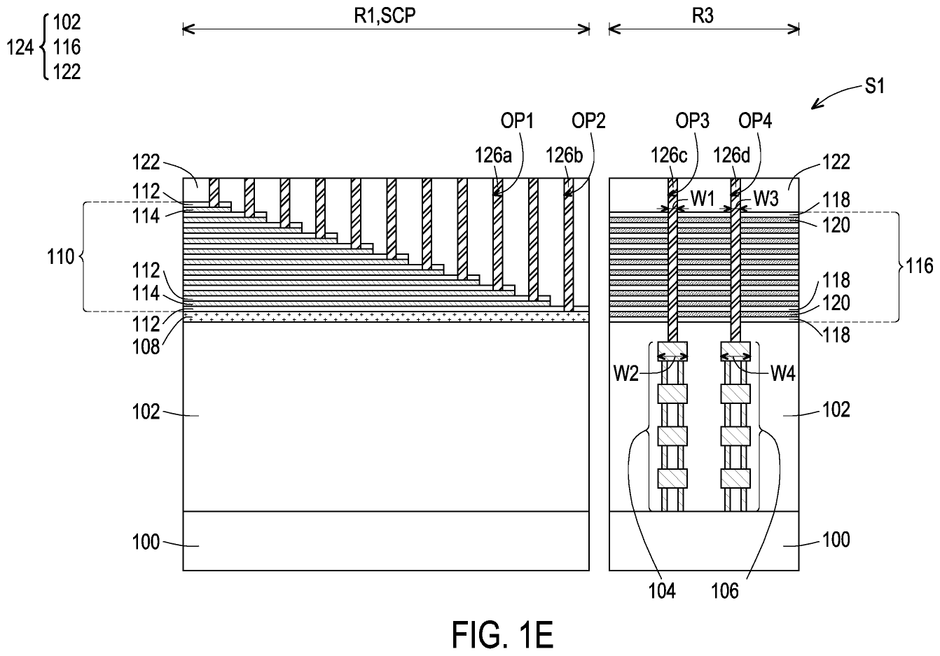

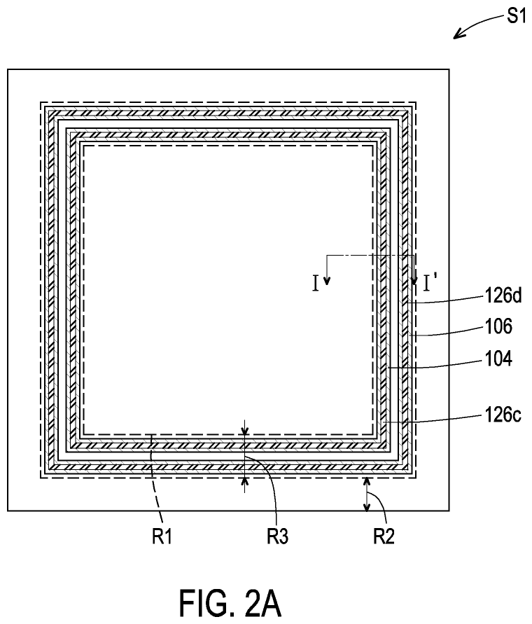

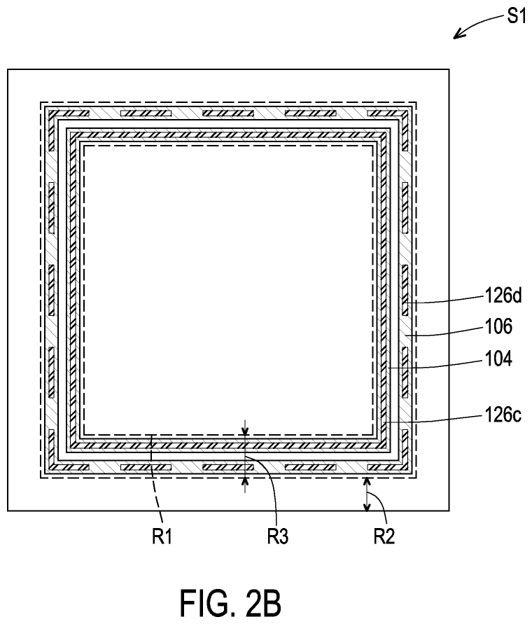

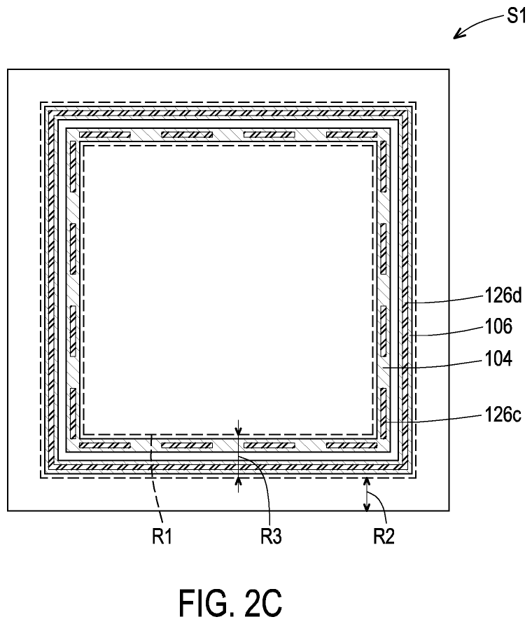

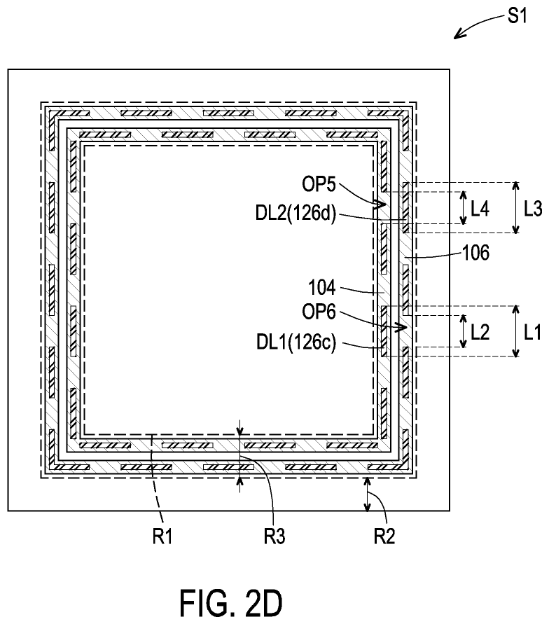

FIG. 1A to FIG. 1E are cross-sectional views of a manufacturing process of a semiconductor structure according to some embodiments of the invention. FIG. 2A is a top view of a semiconductor structure according to some embodiments of the invention. In addition, in FIG. 2A, some components in FIG. 1E are omitted to clearly illustrate the configuration relationship between the components in FIG. 2A. FIG. 1A to FIG. 1E are cross-sectional views taken along section line I-I′ in FIG. 2A. FIG. 2B is a top view of a semiconductor structure according to other embodiments of the invention. FIG. 2C is a top view of a semiconductor structure according to other embodiments of the invention. FIG. 2D is a top view of a semiconductor structure according to other embodiments of the invention.

Referring to FIG. 1A and FIG. 2, a substrate 100 is provided. The substrate 100 includes a device region R1. The device region R1 may be a region used to form a semiconductor device (e.g., active device or passive device). In some embodiments, the substrate 100 may further include a scribe line region R2. The scribe line region R2 may surround the device region R1. In some embodiments, the substrate 100 may further include a seal ring region R3. The seal ring region R3 may be located between the device region R1 and the scribe line region R2. In some embodiments, the substrate 100 may be a semiconductor substrate such as silicon substrate.

In some embodiments, there may be a dielectric layer 102 on the substrate 100. In some embodiments, the dielectric layer 102 may be a multilayer structure. In some embodiments, the required semiconductor device (e.g., active device (such as transistor) and/or passive device) and/or interconnect structure may be formed on the substrate 100 and/or in the dielectric layer 102, and the description thereof is omitted here.

In some embodiments, a seal ring structure 104 may be formed in the dielectric layer 102 in the seal ring region R3. The seal ring structure 104 surrounds the device region R1. In some embodiments, the seal ring structure 104 may be a multilayer structure. In some embodiments, the material of the seal ring structure 104 may include metal, such as tungsten, titanium, titanium nitride, or a combination thereof. In some embodiments, a seal ring structure 106 may be formed in the dielectric layer 102 in the seal ring region R3. The seal ring structure 106 may surround the seal ring structure 104. In some embodiments, the seal ring structure 106 may be a multilayer structure. In some embodiments, the material of the seal ring structure 106 may include metal, such as tungsten, titanium, titanium nitride, or a combination thereof. In some embodiments, a conductive layer 108 may be formed on the dielectric layer 102. In some embodiments, the material of the conductive layer 108 is, for example, doped polysilicon.

In some embodiments, a stack structure 110 may be formed on the dielectric layer 102 in the device region R1. The conductive layer 108 may be located between the stack structure 110 and the dielectric layer 102. The conductive layer 108 may be used for grounding. The material of the conductive layer 108 may be doped polysilicon. The stack structure 110 may include dielectric layers 112 and conductive layers 114 arranged alternately. The stack structure 110 may have a staircase portion SCP. In some embodiments, the material of the dielectric layer 112 is, for example, silicon oxide. In some embodiments, the conductive layer 114 may be used as a word line. In some embodiments, the material of the conductive layer 114 may include metal, such as tungsten, titanium, titanium nitride, or a combination thereof.

In addition, a dielectric stack structure 116 is formed on the dielectric layer 102 in the seal ring region R3. The dielectric stack structure 116 may include dielectric layers 118 and dielectric layers 120 arranged alternately. In some embodiments, the material of the dielectric layer 118 is, for example, silicon oxide. In some embodiments, the material of the dielectric layer 120 is, for example, silicon nitride.

In addition, a dielectric layer 122 may be formed on the stack structure 110 and the dielectric stack structure 116. The dielectric layer 122 may be a single-layer structure or a multilayer structure. In some embodiments, the material of the dielectric layer 122 is, for example, silicon oxide.

By the above method, a dielectric structure 124 may be formed on the substrate 100, the seal ring structure 104 may be formed in the dielectric structure 124, the seal ring structure 106 may be formed in the dielectric structure 124, and the stack structure 110 may be formed in the dielectric structure 124 in the device region R1. The dielectric structure 124 may include the dielectric layer 102 and the dielectric layer 122 located in the device region R1 and the dielectric layer 102, the dielectric stack structure 116, and the dielectric layer 122 located in the seal ring region R3.

Referring to FIG. 1B, openings OP1 may be formed in the dielectric structure 124. The openings OP1 are located in the device region R1 and expose the conductive layers 114. The opening OP1 may pass through the dielectric layer 112. In some embodiments, an opening OP2 may be formed in the dielectric structure 124. The opening OP2 is located in the device region R1 and exposes the conductive layer 108. The opening OP2 may pass through the dielectric layer 112. In some embodiments, the dielectric structure 124 and the dielectric layer 112 may be patterned by a lithography process and an etching process to form the opening OP1 and the opening OP2.

Referring to FIG. 1C, an opening OP3 may be formed in the dielectric structure 124. The opening OP3 is located in the seal ring region R3 and exposes the seal ring structure 104. In some embodiments, an opening OP4 may be formed in the dielectric structure 124. The opening OP4 is located in the seal ring region R3 and exposes the seal ring structure 106. In some embodiments, the dielectric structure 124 may be patterned by a lithography process and an etching process to form the opening OP3 and the opening OP4. In the etching process for forming the opening OP3 and the opening OP4, the seal ring structure 104 and the seal ring structure 106 can be used as etch stop layers. Therefore, the dielectric structure 124 can be prevented from cracking during the above etching process.

Referring to FIG. 1D, a conductive material layer 126 may be formed in the openings OP1, the opening OP2, the opening OP3, and the opening OP4 and on the dielectric structure 124. In some embodiments, the material of the conductive material layer 126 may include metal, such as tungsten, titanium, titanium nitride, or a combination thereof. In some embodiments, the method of forming the conductive material layer 126 is, for example, a physical vapor deposition (PVD) method or a chemical vapor deposition (CVD) method.

Referring to FIG. 1E, the conductive material layer 126 located outside the openings OP1, outside the opening OP2, outside the opening OP3, and outside the opening OP4 is removed to form contacts 126a, a contact 126b, a seal via 126c, and a seal via 126d. Therefore, the contacts 126a, the contact 126b, the seal via 126c, and the seal via 126d may be formed in the dielectric structure 124. The contacts 126a may be electrically connected to the conductive layers 114 in the staircase portion SCP. The contact 126b may be electrically connected to the conductive layer 108. The seal ring structure 104, the seal ring structure 106, the seal via 126c, and the seal via 126d are located in the seal ring region R3. The seal via 126c is in direct contact with the seal ring structure 104. The seal via 126d may be in direct contact with the seal ring structure 106. In some embodiments, the seal via 126c and the seal via 126d may be slot vias. In some embodiments, the method of removing the conductive material layer 126 located outside the openings OP1, outside the opening OP2, outside the opening OP3, and outside the opening OP4 is, for example, a chemical mechanical polishing (CMP) method. In the above embodiments, the contacts 126a, the contact 126b, the seal via 126c, and the seal via 126d may be simultaneously formed by the same process.

Hereinafter, the semiconductor structure S1 of the present embodiment will be described with reference to FIG. 1E. In addition, although the method for forming the semiconductor structure S1 is described by taking the above method as an example, the invention is not limited thereto.

Referring to FIG. 1E and FIG. 2A, a semiconductor structure S1 includes s substrate 100, a dielectric structure 124, a seal ring structure 104, and a seal via 126c. The substrate 100 includes a device region R1. The device region R1 may be an active device region or a passive device region. In some embodiments, the device region R1 may be a memory region. In some embodiments, the memory region may be a 3D AND flash memory region, but the invention is not limited thereto. In some embodiments, the substrate 100 may further include a scribe line region R2. The scribe line region may surround the device region R1. In some embodiments, the substrate 100 may further include a seal ring region R3. The seal ring region R3 may be located between the device region R1 and the scribe line region R2.

The dielectric structure 124 is located on the substrate 100. The seal ring structure 104 is located in the dielectric structure 124. In some embodiments, the seal ring structure 104 may be a die seal ring structure. The seal ring structure 104 surrounds the device region R1. The seal ring structure 104 may be located in the seal ring region R3. The seal ring structure 104 may be located between the device region R1 and the scribe line region R2. In some embodiments, the material of the seal ring structure 104 may include metal, such as tungsten, titanium, titanium nitride, or a combination thereof. The seal via 126c is located in the dielectric structure 124. In some embodiments, the seal via 126c may be a die seal via (DSV). The seal via 126c surrounds the device region R1. The seal via 126c is located on the seal ring structure 104. The seal via 126c may be located directly above the seal ring structure 104. The seal via 126c is in direct contact with the seal ring structure 104. In some embodiments, the maximum width W1 of the seal via 126c may be smaller than the maximum width W2 of the seal ring structure 104. In some embodiments, as shown in FIG. 2A, the top-view pattern of the seal via 126c may be a solid ring shape. In some embodiments, the material of the seal via 126c may include metal, such as tungsten, titanium, titanium nitride, or a combination thereof.

In some embodiments, the semiconductor structure S1 may further include a seal ring structure 106 and a seal via 126d. The seal ring structure 106 is located in the dielectric structure 124. In some embodiments, the seal ring structure 106 may be a die seal ring structure. The seal ring structure 106 may surround the seal ring structure 104. The seal ring structure 106 may be located in the seal ring region R3. The seal ring structure 106 may be located between the device region R1 and the scribe line region R2. In some embodiments, the material of the seal ring structure 106 may include metal, such as tungsten, titanium, titanium nitride, or a combination thereof. The seal via 126d is located in the dielectric structure 124. In some embodiments, the seal via 126d may be a die seal via. The seal via 126d may surround the seal via 126c. The seal via 126d is located on the seal ring structure 106. The seal via 126d may be located directly above the seal ring structure 106. The seal via 126d may be in direct contact with the seal ring structure 106. In some embodiments, the maximum width W3 of the seal via 126d may be smaller than the maximum width W4 of the seal ring structure 106. In some embodiments, the material of the seal via 126d may include metal, such as tungsten, titanium, titanium nitride, or a combination thereof.

In the present embodiment, as shown in FIG. 2A, the top-view pattern of the seal via 126c may be a solid ring shape, and the top-view pattern of the seal via 126d may be a solid ring shape, but the invention is not limited thereto. In other embodiments, as shown in FIG. 2B, the top-view pattern of the seal via 126c may be a solid ring shape, and the top-view pattern of the seal via 126d may be a dashed ring shape. In other embodiments, as shown in FIG. 2C, the top-view pattern of the seal via 126c may be a dashed ring shape, and the top-view pattern of the seal via 126d may be a solid ring shape. In other embodiments, as shown in FIG. 2D, the top-view pattern of the seal via 126c may be a dashed ring shape, and the top-view pattern of the seal via 126d may be a dashed ring shape.

In addition, in the embodiment of FIG. 2D, the top-view pattern of the seal via 126c may include line portions DL1 and openings OP5 arranged alternately. The top-view pattern of the seal via 126d may include line portions DL2 and openings OP6 arranged alternately. The line portions DL1 may be aligned with the openings OP6. The length L1 of each of the line portions DL1 may be greater than or equal to the length L2 of each of the openings OP6. The line portions DL2 may be aligned with the openings OP5. The length L3 of each of the line portions DL2 may be greater than or equal to the length L4 of each of the openings OP5.

In some embodiments, the semiconductor structure S1 may further include a conductive layer 108. In the present embodiment, as shown in FIG. 1E, the conductive layer 108 is located between the stack structure 110 and the dielectric layer 102 in the device region R1, but the invention is not limited thereto. In other embodiments, although not shown in the figure, the conductive layer 108 may be further located between the dielectric stack structure 116 and the dielectric layer 102 in the seal ring region R3, the seal vias 126c and 126d pass through the conductive layer 108 in the ring region R3, and there is a dielectric material between the conductive layer 108 and the seal vias 126c and 126d to insulate the conductive layer 108 from the sealed vias 126c and 126d.

Furthermore, the remaining components in the semiconductor structure S1 may refer to the description of the above embodiments. Moreover, the details (e.g., material and forming method) of the components in the semiconductor structure S1 have been described in detail in the above embodiments, and the description thereof is not repeated here.

Based on the above embodiments, in the semiconductor structure S1 and the manufacturing method thereof, the seal via 126c is located on the seal ring structure 104, and the seal via 126c is in direct contact with the seal ring structure 104. In this way, during the process of forming the seal via 126c, the etching process can be performed on the dielectric structure 124 by using the seal ring structure 104 as an etch stop layer to form the opening OP3 for accommodating the seal via 126c. Therefore, the dielectric structure 124 can be prevented from cracking during the above etching process, thereby preventing the semiconductor structure S1 from being damaged.

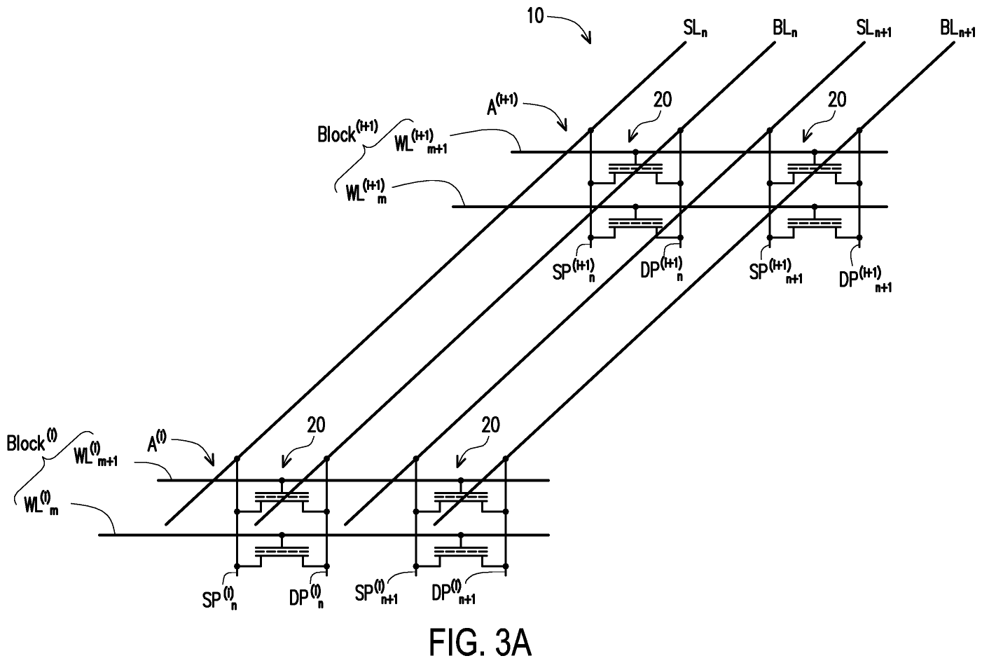

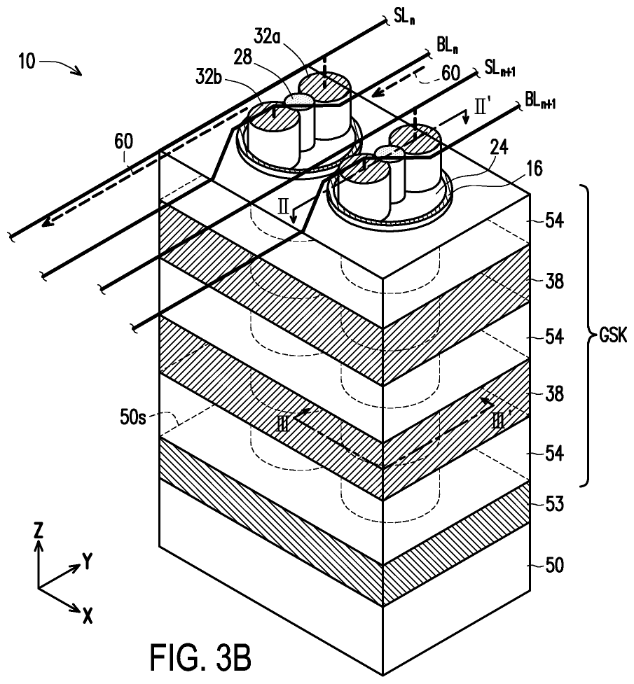

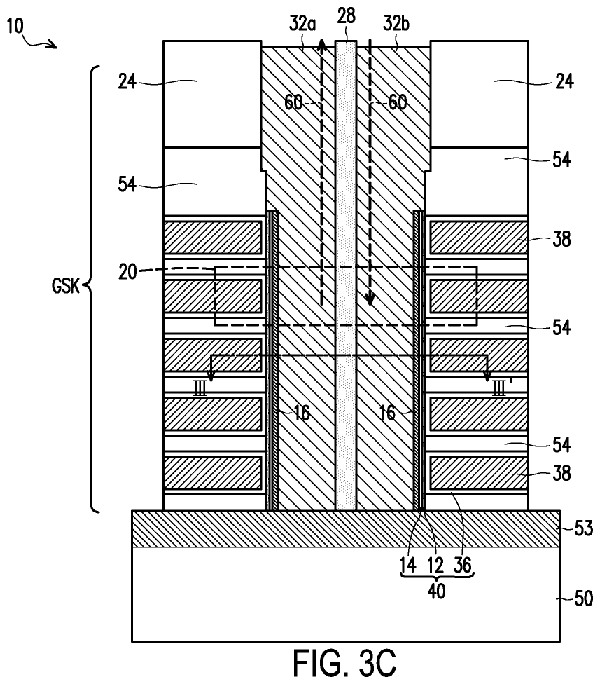

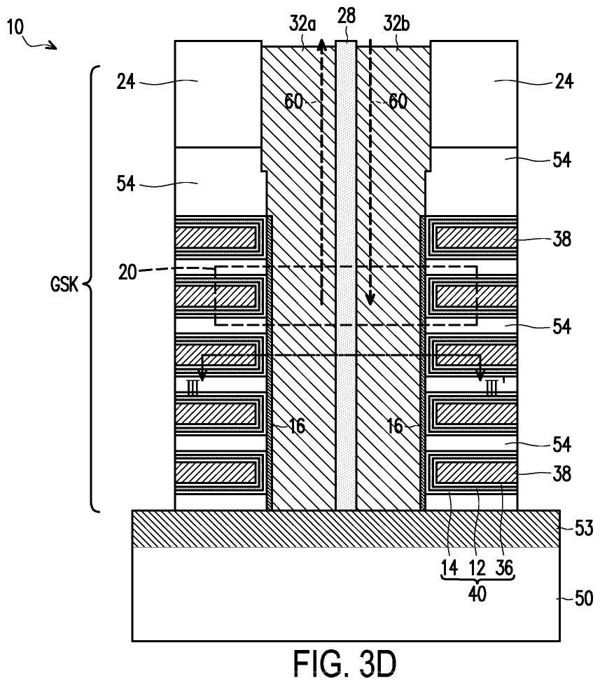

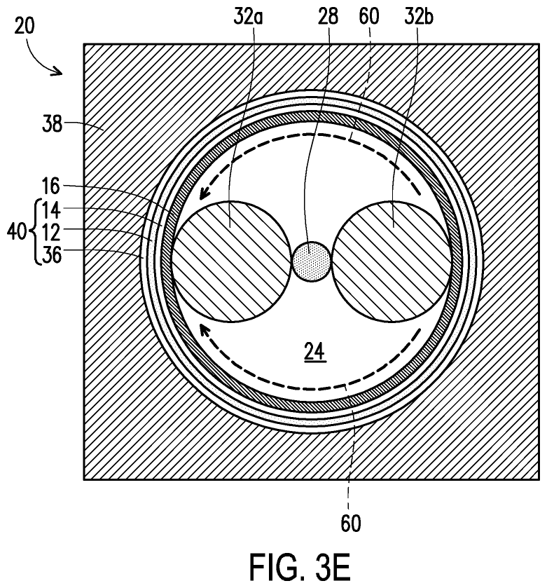

The semiconductor structure and the manufacturing method thereof of the above embodiments may be applied to a memory such as a 3D AND flash memory or 3D NOR flash memory. Hereinafter, the 3D AND flash memory is described with reference to FIG. 3A to FIG. 3E.

FIG. 3A is a circuit diagram of a 3D AND flash memory array according to some embodiments of the invention. FIG. 3B is a partial perspective view of a part of the memory array in FIG. 3A. FIG. 3C and FIG. 3D are cross-sectional views taken along section line II-II′ in FIG. 3B. FIG. 3E is a top view of section line III-III′ in FIG. 3B, FIG. 3C, and FIG. 3D.

In some embodiments, the device in the device region R1 in the above semiconductor structure S1 may be replaced with the memory array 10 as shown in FIG. 3A to FIG. 3E.

FIG. 3A is a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 3A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 3B to FIG. 3D, the memory array 10 may be disposed over an interconnect structure of a semiconductor die, for example, being disposed on one or more active devices (e.g., transistors) formed on a semiconductor substrate. Therefore, a dielectric substrate (or called dielectric layer) 50 may be a dielectric layer (e.g., a silicon oxide layer) over a metal interconnect structure formed on a silicon substrate. The memory array 10 may include a stack structure GSK, channel pillars 16, first conductive pillars (also referred to as source pillars) 32a, second conductive pillars (also referred to as drain pillars) 32b, and charge storage structures 40.

Referring to FIG. 3B, the stack structure GSK is formed on the dielectric substrate 50. The stack structure GSK includes gate layers (also referred to as word lines or conductive layers) 38 and insulating layers 54 vertically stacked on the surface 50s of the dielectric substrate 50. In a direction Z, the gate layers 38 are electrically isolated from each other by the insulating layer 54 disposed therebetween. The gate layers 38 extend in a direction parallel to the surface of the dielectric substrate 50. The gate layers 38 in the staircase region may have a staircase structure. Therefore, a lower gate layer 38 is longer than an upper gate layer 38, and the end of the lower gate layer 38 extends laterally beyond the end of the upper gate layer 38. Contacts (not shown) for connecting the gate layers 38 may be landed on the ends of the gate layers 38 to connect the gate layers 38 respectively to conductive lines.

Referring to FIG. 3B to FIG. 3D, the memory array 10 further includes channel pillars 16. The channel pillars 16 extend continuously through the stack structure GSK and to the conductive layer 53 between the dielectric substrate 50 and the stack structure GSK. The material of the conductive layer 53 may include doped polysilicon. For example, the material of the conductive layer 53 may include P-type doped polysilicon. In some embodiments, each channel pillar 16 may have a ring shape from a top view. The material of the channel pillars 16 may include semiconductor such as undoped polysilicon.

Referring to FIG. 3B to FIG. 3D, the memory array 10 further includes insulating pillars 28, first conductive pillars 32a, and second conductive pillars 32b. In this example, the first conductive pillars 32a serve as source pillars. The second conductive pillars 32b serve as drain pillars. The first conductive pillars 32a, the second conductive pillars 32b, and the insulating pillars 28 each extend in a direction (i.e., the direction Z) perpendicular to the surface (i.e., the X-Y plane) of the gate layer 38. The first conductive pillar 32a and the second conductive pillar 32b are separated by the insulating pillar 28 and surrounded by an insulating filling layer 24. The first conductive pillar 32a and the second conductive pillar 32b are electrically connected to the channel pillar 16. The first conductive pillar 32a and the second conductive pillar 32b may include doped polysilicon or metal materials. The insulating pillar 28 may include silicon nitride or silicon oxide, and the insulating filling layer 24 may include silicon oxide.

Referring to FIG. 3C and FIG. 3D, a charge storage structure 40 is disposed between the channel pillar 16 and the gate layers (or called conductive layers) 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 3C, a portion (e.g., the tunneling layer 14 and the charge storage layer 12) of the charge storage structure 40 continuously extends in a direction (i.e., the direction Z) perpendicular to the gate layer 38, and another portion (e.g., the blocking layer 36) of the charge storage structure 40 surrounds the gate layer 38. In other embodiments, as shown in FIG. 3D, the charge storage structure 40 (e.g., the tunneling layer 14, the charge storage layer 12, and the blocking layer 36) surrounds the gate layer 38.

Referring to FIG. 3E, the charge storage structure 40, the channel pillar 16, the source pillar 32a, and the drain pillar 32b are surrounded by the gate layer 38, and a memory cell 20 is accordingly defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vₜₕ) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 3B), flow to the source pillar 32a via the turned-on channel region (e.g., in a direction indicated by arrow 60), and finally flow to the source line SLₙ or SLₙ₊₁ (shown in FIG. 3B).

In summary, in the semiconductor structure and the manufacturing method thereof in the aforementioned embodiments, the seal via is located on the seal ring structure, and the seal via is in direct contact with the seal ring structure. In this way, during the process of forming the seal via, the etching process can be performed on the dielectric structure by using the seal ring structure as an etch stop layer to form the opening for accommodating the seal via. Therefore, the dielectric structure can be prevented from cracking during the above etching process, thereby preventing the semiconductor structure from being damaged.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate comprising a device region;
a dielectric structure located on the substrate;
a first seal ring structure located in the dielectric structure and surrounding the device region; and
a first seal via located in the dielectric structure and surrounding the device region, wherein the first seal via is located on the first seal ring structure, and the first seal via is in direct contact with the first seal ring structure.

2. The semiconductor structure according to claim 1, wherein the device region comprises an active device region or a passive device region.

3. The semiconductor structure according to claim 2, wherein the device region comprises a memory region.

4. The semiconductor structure according to claim 3, wherein the memory region comprises a three-dimensional AND flash memory region.

5. The semiconductor structure according to claim 1, wherein the substrate further comprises a scribe line region, the scribe line region surrounds the device region, and the seal ring structure is located between the device region and the scribe line region.

6. The semiconductor structure according to claim 1, wherein the first seal via is located directly above the first seal ring structure.

7. The semiconductor structure according to claim 1, wherein a maximum width of the first seal via is smaller than a maximum width of the first seal ring structure.

8. The semiconductor structure according to claim 1, wherein a material of the first seal ring structure comprises metal, and a material of the first seal via comprises metal.

9. The semiconductor structure according to claim 1, wherein a top-view pattern of the first seal via is a solid ring shape.

10. The semiconductor structure according to claim 1, further comprising:
a second seal ring structure located in the dielectric structure and surrounding the first seal ring structure; and
a second seal via located in the dielectric structure and surrounding the first seal via, wherein the second seal via is located on the second seal ring structure, and the second seal via is in direct contact with the second seal ring structure.

11. The semiconductor structure according to claim 10, wherein a top-view pattern of the first seal via is a solid ring shape, and a top-view pattern of the second seal via is a solid ring shape.

12. The semiconductor structure according to claim 10, wherein a top-view pattern of the first seal via is a solid ring shape, and a top-view pattern of the second seal via is a dashed ring shape.

13. The semiconductor structure according to claim 10, wherein a top-view pattern of the first seal via is a dashed ring shape, and a top-view pattern of the second seal via is a solid ring shape.

14. The semiconductor structure according to claim 10, wherein a top-view pattern of the first seal via is a dashed ring shape, and a top-view pattern of the second seal via is a dashed ring shape.

15. The semiconductor structure according to claim 14, wherein
the top-view pattern of the first seal via comprises first line portions and first openings arranged alternately,
the top-view pattern of the second seal via comprises second line portions and second openings arranged alternately,
the first line portions are aligned with the second openings,
a length of each of the first line portions is greater than or equal to a length of each of the second openings,
the second line portions are aligned with the first openings, and
a length of each of the second line portions is greater than or equal to a length of each of the first openings.

16. A manufacturing method of a semiconductor structure, comprising:
providing a substrate, wherein the substrate comprises a device region;
forming a dielectric structure on the substrate;
forming a first seal ring structure in the dielectric structure, wherein the first seal ring structure surrounds the device region; and
forming a first seal via in the dielectric structure, wherein the first seal via surrounds the device region, the first seal via is located on the first seal ring structure, and the first seal via is in direct contact with the first seal ring structure.

17. The manufacturing method of the semiconductor structure according to claim 16, further comprising:
forming a stack structure in the dielectric structure in the device region, wherein the stack structure comprises dielectric layers and conductive layers arranged alternately, and the stack structure has a staircase portion; and
forming contacts in the dielectric structure, wherein the contacts are electrically connected to the conductive layers in the staircase portion.

18. The manufacturing method of the semiconductor structure according to claim 17, wherein the contacts and the first seal via are simultaneously formed by the same process.

19. The manufacturing method of the semiconductor structure according to claim 17, wherein the substrate further comprises a seal ring region, the first seal ring structure and the first seal via are located in the seal ring region, and a method of forming the contacts and the first seal via comprises:
forming first openings in the dielectric structure, wherein the first openings are located in the device region and expose the conductive layers;
forming a second opening in the dielectric structure, wherein the second opening is located in the seal ring region and exposes the first seal ring structure;
forming a conductive material layer in the first openings and the second opening and on the dielectric structure; and
removing the conductive material layer located outside the first openings and outside the second opening to form the contacts and the first seal via.

20. The manufacturing method of the semiconductor structure according to claim 16, further comprising:
forming a second seal ring structure in the dielectric structure, wherein the second seal ring structure surrounds the first seal ring structure; and
forming a second seal via in the dielectric structure, wherein the second seal via surrounds the first seal via, the second seal via is located on the second seal ring structure, and the second seal via is in direct contact with the second seal ring structure.
